(19) United States
(12) Patent Application Publication
(10) Pub. No.: US 2005/0226275 A1
(43) Pub. Date: Oct. 13, 2005

(54) Local transmission system for a vehicle

(75) Inventors: Michael Jordan Hrycaj, Neu-Isenburg (DE); Friedrich Kuebler, Boeblingen (DE)

Correspondence Address: CROWELL & MORING LLP;INTELLECTUAL PROPERTY GROUP, P.O. BOX 14300, WASHINGTON, DC, 20044-4300, US

(73) Assignee: DaimlerChrysler AG, Stuttgart (DE)

(21) Appl. No.: 11/087,858

(22) Filed: Mar. 24, 2005

(30) Foreign Application Priority Data
Mar. 25, 2004 (DE) 10 2004 014 624.1

(51) Int. Cl. H04B 7/216; G06F 11/00; H04L 1/18; H04J 3/24; G01R 31/08; H04J 1/16; H04L 1/00; G08C 15/00; H04L 12/26; H04J 3/14

(52) U.S. Cl. 370/474; 714/749; 370/229

(57) ABSTRACT

A local transmission system for a vehicle comprises a number of stations which are connected to one another for exchanging messages via a databus, each message exhibiting a message frame with a predetermined structure. A data block to be transmitted is divided into N data packets which are successively transmitted as messages to the at least one receiver station, which individually acknowledges the reception of each of the messages, including the last such message of a data block, by sending an acknowledgement message. The transmitter station transmits a next successive message only if the acknowledgement message for the previous message has been received. Before sending each message, the transmitter station calculates an adjustable delay period, and only transmits such message only after the calculated delay period has elapsed.

### BACKGROUND AND SUMMARY OF THE INVENTION

This application claims the priority of German patent document 10 2004 014 624.1, filed Mar. 25, 2004, the disclosure of which is expressly incorporated by reference herein.

The invention relates to a local transmission system for vehicles, such as aircraft, ships, trains or motor vehicles.

Such a local transmission system comprises a number of stations which are connected to one another for exchanging messages via a databus, such as a CAN databus, an optical D2B or a MOST databus. The individual stations are able to act as transmitter stations and/or as receiver stations. For transmission, each message exhibits a message frame with a structure that is dependent on the transmission protocol used. Depending on the application, various known protocols can be used for message transmission (for example, D2B or MOST protocols). Thus, in the case of a MOST databus, for example, a MAMAC protocol MOST Asynchronous Medium Access Control) can be used, which makes it possible to transmit Internet protocol (IP) data blocks on an asynchronous channel via the MOST databus.

Special interest has been focused on the MAMAC protocol (particularly MAMAC48) because it can be implemented using an inexpensive, simple hardware architecture. However, one disadvantage of this transmission protocol is that messages transmitted from a transmitter station to a receiver station can get lost without being noticed by the transmitter station.

In the MAMAC48 protocol, the transmitter station splits the IP data block to be transmitted into suitable 48-byte-large data fragments and transmits them successively to the receiver station as individual messages. The receiver station acknowledges the reception of each message individually by an acknowledgement message transmitted to the transmitter station (except that the reception of the last data fragment is not acknowledged). This also applies to data blocks, the amounts of which are in each case transmitted by means of a single message (i.e., a last message). The transmitter station transmits a further message including the data block only when the associated acknowledgement message for the previous message has been received.

The receiver station assembles the individually received data fragments again to form a complete IP data block. After the reception of one of these 48 byte data fragments, the receiver station is blocked (that is, it cannot receive any further data fragments) for the duration of a particular dead time, which depends on how fast a received data fragment is read out of the associated receive memory.

The transmitted message frame comprises fields for a transmitter address, a receiver address, a data type (i.e., useful data or received acknowledgement), a number of the current data fragment, a total number of data fragments and fields for useful data. The messages can be sent to an individual receiver station, or to some or all receiver stations within the transmission system. If the transmitter station does not receive an expected acknowledgement message, it aborts the transmission of the data block and all data fragments belonging to this data block are discarded. The transmitter station then recommences the process of transmitting the data block.

With this transmission protocol, messages can get lost unnoticed, for example if the last message with the last data fragment is not received by the receiver station (since this will not be noticed by the transmitter station). This also applies to data blocks which are transmitted with only one message. A loss can occur, for example, if a message arrives at the receiver within its dead time and cannot, therefore, be accepted by the receiver.

Since the physical transmission capacity on the MOST databus far exceeds the receive capacity of the MAMAC48 receive memories, there will always be situations in which data are lost unnoticed at the receiver.

One object of the invention is to provide a local transmission system for a vehicle which transmits messages largely without losses, and can nevertheless can be equipped with simple and inexpensive hardware architecture.

This and other objects and advantages are achieved by the local transmission system according to the invention, in which a receiver station also acknowledges the reception of a last transmitted message of a data block, by means of a corresponding acknowledgement message sent to a transmitter station. In addition, before sending one of the messages, the transmitter station calculates an adjustable delay period and sends each of the messages to the receiver station only after the calculated delay period has elapsed. Acknowledgement of the reception of the last transmitted message of a data block advantageously ensures that none of the messages is lost. Due to the adjustable delay time, the transmitting station can adapt the transmission rate of the messages to the dead time existing in the receiver station, and avoid a further message from being received by the receiver station within its dead time.

As an embodiment of the local transmission system, an off period can be predetermined in the transmitter station, which is activated after one of the messages has been sent. During this off period, the transmitting station waits for reception of the associated acknowledgement message. If the latter does not appear within the predeterminable off period, the transmitter station repeats the message to the receiver station, further increasing the reliability of transmission, and avoiding having to resend the entire data block (for example due to a short-term disturbance on the databus).

As a further embodiment of the local transmission system, the transmitter station aborts the transmission of the data block if the acknowledgement message for the repeated message also fails to arrive.

In a particularly advantageous embodiment of the local transmission system according to the invention, the transmitter station recalculates the delay time after failing to receive an acknowledgement message, taking into consideration an integral multiple of an estimated receiver-related dead period of the at least one receiver station. As a result, the transmission of the messages can be advantageously optimally adapted to the transmission link and/or the reception characteristics of the associated receiver station.

The integral multiple is calculated, for example, by means of a random generator in dependence on an associated network node, and is preferably within the numerical range from 1 to 15. This ensures that the same delay time is not used at the same time by two transmitter stations of the transmission system.

The transmitting station can determine the receiver-related dead time of a receiving station, for example, as a constant numerical value.

As an alternative, the transmitting station can calculate the receiver-related dead time as a sliding average of a predeterminable number of transmission times (preferably, from the last three transmissions) which in each case elapse between the sending out of a message and the subsequent reception of the associated acknowledgement message.

In a further embodiment of the local transmission system, the transmitting station sets the last three transmission times to a predetermined initial value (preferably to 500 μs), during the initialization of the transmission system.

During the initialization of the transmission system, the transmitter station initializes the delay times with a predetermined numerical value, preferably with the numerical value zero.

The predetermined size of the data fragments is, for example, 48 bytes.

Other objects, advantages and novel features of the present invention will become apparent from the following detailed description of the invention when considered in conjunction with the accompanying drawings.

### BRIEF DESCRIPTION OF THE DRAWINGS

FIG. 1 is a conceptual block diagram of an illustrative embodiment of a local transmission system according to the invention; and

FIG. 2 is a diagrammatic representation of the events in transmitter and a receiver stations of the transmission system of FIG. 1.

### DETAILED DESCRIPTION OF THE INVENTION

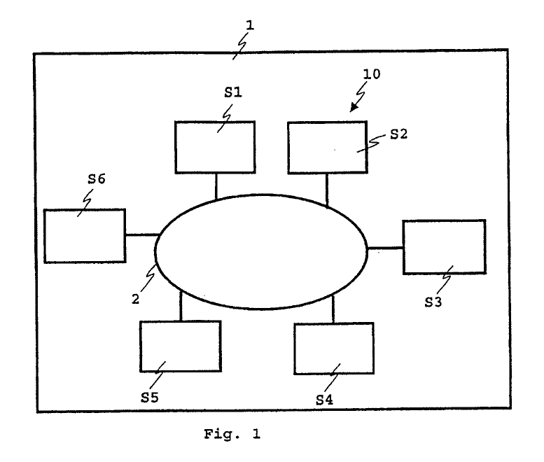

As can be seen from FIG. 1, a local transmission system 10 in a vehicle 1 comprises a number of stations S1 to S6, which are connected to one another for exchanging messages via a databus 2 (for example, a CAN databus, or an optical D2B or MOST databus). The stations S1 to S6 can act as transmitter station SS and/or as receiver station ES.

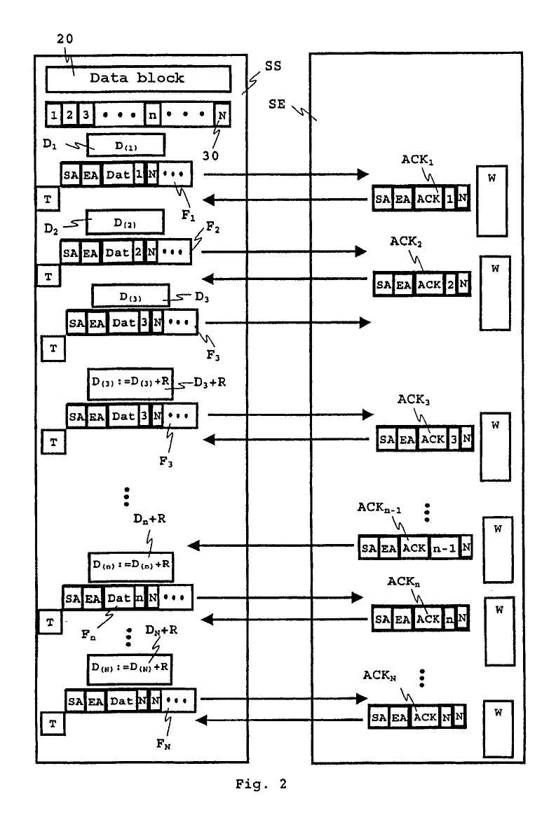

To explain the operation of the local transmission system, FIG. 2 shows by way of example a station acting as transmitter station SS and a station acting as receiver station ES of the transmission system 10. As can be seen from FIG. 2, a data block 20 to be transmitted is divided in the transmitter station SS into N data fragments 30 (with a predetermined size of, for example 48 bytes) which are in each case successively transmitted as part of a message F₁ to F_{N} to the receiver station ES. The receiver station ES acknowledges the reception of all messages F₁ to F_{N} transmitted by the transmitting station SS in each case individually by an acknowledgement message ACK₁ to ACK_{N} transmitted to the transmitter station SS. The transmitter station SS sends a message Fₙ to the receiver station ES only when the acknowledgement message ACKₙ₋₁ for the previous message Fₙ₋₁ has been received in the transmitting station SS.

Each of the messages F₁ to F_{N} comprises a message frame with a predetermined structure. According to this structure, such a message frame comprises the fields transmitter address SA, receiver address (where, for example, an actual address of a receiver station or a group of receiver stations or all receiver stations can be entered as receiver), message type (i.e., data or acknowledgement signal), number of the current data fragment, total number of data fragments to be transmitted and useful data which have a maximum length of 48 bytes. The structure of the message frame for one of the acknowledgement messages ACK₁ to ACK_{N} corresponds to the structure of the message frame for transmitting the data fragments except that the message type ACK for acknowledgement message is entered and no useful data are transmitted. As the transmitter address, the address of the transmitter station SS is entered during the transmission of the data fragments and the address of the receiver station ES is entered during the transmission of the acknowledgement messages. As a receiver address, the address of the receiver station ES is entered during the transmission of the data fragments and the address of the transmitter station SS is entered during the transmission of the acknowledgement messages.

As can also be seen from FIG. 2, before sending one of the message F₁ to F_{N}, the transmitter station SS calculates an adjustable delay period D₁ to D_{N} and sends the respective message F₁ to F_{N} to the receiver station ES only after the calculated delay period D₁ to D_{N} has elapsed. During the initialization of the transmission system 10, the transmitter station SS initializes the delay times D₁ to D_{N} with a predetermined numerical value, preferably zero. For this reason, the first three delay times D₁ to D₃ shown are in each case set to the value zero (i.e., the transmitter station SS sends the next message F₂ or F₃ directly after reception of the acknowledgement message ACK₁ or ACK₂ for the previous message F₁ or, respectively, F₂ to the receiver station ES). In addition, the transmission of one of the messages F₁ to F_{N} starts a counting loop or a counter which provides a predetermined off period T during which the transmitter station SS, after sending one of the messages F₁ to F_{N}, waits for the reception of the associated acknowledgement message ACK₁ to ACK_{N}. After the predetermined off period T has elapsed, the message Fₙ is sent again if no associated acknowledgement message ACK_{N} is received for the transmitted message Fₙ. The off period for detecting losses of messages can be adapted to the capabilities of reception of the receiver and is an integral multiple, preferably within the numerical range from 2 to 5, of a receiver-related dead time W estimated by the transmitter station SS.

FIG. 2 shows such a loss of message in conjunction with the third message F₃. As can be seen from FIG. 2, after the first transmission, the message F₃ is not acknowledged by the associated acknowledgement message ACK₃ by the receiver station ES within the off period T. The reason for this is, for example, that the message F₃ is transmitted too rapidly to the receiver station ES and arrives there during the receiver-related dead time W. After the reception of one of the messages F₁ to F_{N}, the receiver station ES is in each case blocked for the duration of the receiver-related dead time W (i.e., the receiver station cannot receive any further messages F₁ to F_{N} for the duration of the dead time W). The dead time is dependent on, for example, how rapidly a received data fragment is read out of the associated receive memory.

After the failure of the acknowledgement message ACK₃ to appear, the transmitter station SS recalculates the delay time D₃ for the message F₃ and the delay times D₄ to D_{N} of the subsequent messages F₄ to F_{N}, taking into consideration an integral multiple of the receiver-related dead period W of the receiver station ES. In addition, the off period T for detecting message losses is also recalculated.

To calculate the new delay times D₃ to D_{N} and the new off-period T, the transmitter station SS estimates the receiver-related dead period W. To calculate the new delay times D₃ to D_{N}, the transmitting station SS multiplies the estimated dead period W by an integral multiple which is calculated, for example, in dependence on an associated network node by a random generator. The integral multiple is preferably within the numerical range from 1 to 15.

After that the calculated numerical value R is added to the previous delay period. This results in the new value D₃ₐₗₜ+R for the delay period D₃. The calculated numerical value R is also added to the other delay times so that the delay times D₄ to D_{N} are also extended for all subsequent messages F₄ to F_{N}. If another message loss is noticed during the transmission of one of the subsequent messages F₄ to F_{N}, the off time and the delay times are again recalculated. The delay time Dₙ for the nth message Fₙ thus depends on how successful the transmissions of the previous transmitted messages F₁ to Fₙ₋₁ have been.

In the illustrative embodiment shown, the transmitting station SS calculates the dead time W which in each case elapses between the transmission of a message F₁ to F_{N} and the subsequent reception of the associated acknowledgement message ACK₁ to ACK_{N}, as the sliding average of a predeterminable number of transmission times. That is, the receiver-related dead time W is estimated by the transmitter station SS by means of the transmission times for the respective message F₁ to F_{N} and the associated acknowledgement message ACK₁ to ACK_{N}.

In the illustrative embodiment shown, the transmitting station SS forms the sliding average for estimating the dead time W from the transmission times of the last three messages. These three transmission times needed for calculating the dead time W are set to a predetermined value, for example 500 μs, during the initialization of the transmission system 10, and the set values gradually are updated by the transmission times currently found. During the updating, the value currently found always overwrites the oldest unaltered value stored in the memory. As an alternative, the transmitting station can determine the receiver-related dead time W by using a constant numerical value (for example by 500 μs). If the transmitter station SS also fails to receive an associated acknowledgement message ACK₃ for the repeated message F₃, the transmitter station SS aborts the transmission of the data block 20.

The adjustable off times T, the delay times D₁ to D_{N}, and the estimated dead time W are calculated by the transmitting station relative to their time resolution, and are implemented, for example, as 32-bit register integers. The respective register content is interpreted as a multiple of 100 μs, so that the greatest time which can be represented is then (2³¹⁻¹)*100 μs, and corresponds to approximately 59.7 hours.

The random generator used is, for example, a modified Fibronacci generator using the following algorithm:
X:=X1+X2; X2:=X1; X1:=X;
Y:=Y1+Y2; Y2:=Y1; Y1:=Y;
r:=((X>>1)\hat{ }(Y>>2))& 15;
where all variables X1, X2, Y1 and Y2 are 32-bit-wide registers. The system is initialized with X1:=0; X2:=1+specific node number
Y2:=0, Y1:=1;
The effect of this initialization is that different number sequences are run on different nodes in the transmission system so that the same delay time is not used at the same time by two transmitting stations within the transmission system. The value R for calculating the delay times D₃ to D_{N} is then calculated by means of the formula R=(1+r)*W.

The transmission system according to the invention, in which the reception of the last message of a data block to be transmitted is also acknowledged by an associated acknowledgement message; and an adjustable delay period is calculated and activated before one of the messages is sent, advantageously virtually ensures that none of the messages is lost without being noticed. Due to the adjustable delay time, the transmitting station can adapt the transmission rate of the messages to the dead time existing in the receiver station and avoid receipt of a further message by the receiver station within its dead time. In particular, when the loss of a message is noticed, the delay time is extended for all subsequent messages in order to avoid any further noticeable message loss.

The transmission system according to the invention is particularly suitable for application in transmission systems without data collision detection. The functions delay time Dₙ, off time T, estimation of the dead time W, described, are preferably implemented as software programs, the program code of which is stored in a memory of the transmitter station.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1. A local transmission system for a vehicle, comprising a plurality of stations, including at least one transmitter station and at least one receiver station, which are connected to one another for exchanging messages via a databus, each message exhibiting a message frame with a predetermined structure; wherein:
the at least one transmitter station divides a data block to be transmitted into N data fragments having a predetermined size, and successively transmits each of the data fragments as a message to the at least one receiver station;
the at least one receiver station acknowledges the reception of each of the first N-1 messages individually, by sending an acknowledgement message to the transmitter station;
the transmitter station sends a next successive message only when an acknowledgement message for an immediately previous message has been received;
the at least one receiver station also acknowledges the reception of a last one of the messages of each data block, by means of an acknowledgement message transmitted to the at least one transmitter station; and
before sending each of the messages, the at least one transmitter station calculates an adjustable delay period, and transmits each message to the at least one receiver station (ES) only after the calculated delay period has elapsed.

2. The local transmission system according to claim 1, wherein, after transmitting one of the messages, the at least one transmitter station waits for a predeterminable off period for the reception of the associated acknowledgement message and sends the message again after the predeterminable off period has elapsed if the associated acknowledgement signal is not received within the predetermined off period.

3. The local transmission system according to claim 2, wherein the transmitter station aborts transmission of the data block if an acknowledgement message is not received for the repeated message.

4. The local transmission system according to claim 1, wherein the transmitter station recalculates the delay time after the failure of the acknowledgement message to appear, taking into consideration an integral multiple of a calculated receiver-related dead period.

5. The local transmission system according to claim 4, wherein a random generator calculates the integral multiple in dependence on an associated network node.

6. The local transmittal system according to claim 5, wherein the multiple is within the numerical range from 1 to 15.

7. The local transmission system according to claim 5, wherein the at least one transmitting station determines the estimated dead time (W) as a constant numerical value.

8. The local transmission system according to claim 5, wherein the at least one transmitting station calculates the dead time as a sliding average of a predeterminable number of transmission times which in each case elapse between transmission of a message and subsequent reception of an associated acknowledgement message.

9. The local transmission system according to claim 8, wherein the at least one transmitting station calculates the sliding average based on the last three transmission times.

10. The local transmission system according to claim 9, wherein the at least one transmitting station sets the last three transmission times to a predetermined initial value during the initialization of the transmission system.

11. The local transmission system according to claim 10, wherein said initial value is approximately 500 μsecs.

12. The local transmission system according to claim 10, wherein the at least one transmitter station initializes the delay times to a predetermined numerical value during initialization of the transmission system.

13. The local transmission system according to claim 12, wherein the predetermined initial value is approximately zero.

14. The local transmission system according to claim 13, wherein the predetermined size of the data packets is 48 bytes.
